(19) United States
(12) Patent Application Publication
(10) Pub. No.: US 2026/0026203 A1
(43) Pub. Date: Jan. 22, 2026

(54) DISPLAY DEVICE

(71) Applicant: Japan Display Inc., Tokyo (JP)

(72) Inventors: Tomokazu ISHIKAWA, Tokyo (JP); Sho YANAGISAWA, Tokyo (JP); Hiraaki KOKAME, Tokyo (JP); Ryota TAKASAKI, Tokyo (JP); Takamitsu FUJIMOTO, Tokyo (JP)

(73) Assignee: Japan Display Inc., Tokyo (JP)

(21) Appl. No.: 19/267,695

(22) Filed: Jul. 14, 2025

(30) Foreign Application Priority Data
Jul. 16, 2024 (JP) 2024-113338
Apr. 16, 2025 (JP) 2025-067323

(51) Int. Cl. H10K 59/122; H10K 59/12; H10K 59/80

(52) U.S. Cl. CPC H10K 59/122; H10K 59/8722; H10K 59/873; H10K 59/1201

(57) ABSTRACT

According to one embodiment, a display device includes a substrate having display and surrounding areas, an organic insulating layer in the display and surrounding areas, pixels each including lower and upper electrodes, and an organic layer, a first partition in the display area, a second partition in the surrounding area, a third partition provided further outward than the second partition in the surrounding area and spaced apart from the second partition via a slit, and a dam portion surrounding the organic insulating layer, the second partition, and the third partition. The third partition is located above the organic insulating layer and is spaced apart from the dam portion.

### CROSS-REFERENCE TO RELATED APPLICATIONS

This application is based upon and claims the benefit of priority from Japanese Patent Applications No. 2024-113338, filed Jul. 16, 2024; and No. 2025-067323, filed Apr. 16, 2025, the entire contents of all of which are incorporated herein by reference.

### FIELD

Embodiments described herein relate generally to a display device.

### BACKGROUND

Recently, display devices with organic light-emitting diodes (OLED) applied thereto as display elements have been put into practical use. In this type of display devices, a technique for improving the yield is required.

### BRIEF DESCRIPTION OF THE DRAWINGS

FIG. 1 is a view showing a configuration example of a display device according to the first embodiment.

FIG. 2 is a schematic plan view showing an example of the layout of subpixels.

FIG. 3 is a schematic cross-sectional view of the display device along the III-III line of FIG. 2.

FIG. 4 is a schematic plan view of the display device according to the first embodiment.

FIG. 5 is a schematic plan view in which the area surrounded by the frame V of FIG. 4 is enlarged.

FIG. 6 is a schematic plan view in which part of FIG. 5 is further enlarged.

FIG. 7 is a schematic cross-sectional view of a surrounding area of the display device according to the first embodiment.

FIG. 8 is a schematic plan view of a mother substrate according to the first embodiment.

FIG. 9 is a schematic plan view of a panel unit according to the first embodiment.

FIG. 10 is a flowchart showing an example of the manufacturing method of the display device according to the first embodiment.

FIG. 11A is a schematic cross-sectional view showing the manufacturing process of the display device.

FIG. 11B is a schematic cross-sectional view showing a process following FIG. 11A.

FIG. 11C is a schematic cross-sectional view showing a process following FIG. 11B.

FIG. 11D is a schematic cross-sectional view showing a process following FIG. 11C.

FIG. 11E is a schematic cross-sectional view showing a process following FIG. 11D.

FIG. 11F is a schematic cross-sectional view showing a process following FIG. 11E.

FIG. 11G is a schematic cross-sectional view showing a process following FIG. 11F.

FIG. 12A is a schematic cross-sectional view of a display device according to a comparative example and shows a state where droplets of a resin layer are discharged.

FIG. 12B is a schematic cross-sectional view of the display device according to the comparative example and shows a state where droplets of the resin layer have adhered.

FIG. 13A is a schematic cross-sectional view of the display device according to the first embodiment and shows a state where droplets of the resin layer are discharged.

FIG. 13B is a schematic cross-sectional view of the display device according to the first embodiment and shows a state where droplets of the resin layer have adhered.

FIG. 14 is a schematic cross-sectional view of a surrounding area of a display device according to the second embodiment.

FIG. 15 is a schematic plan view showing the configuration of a display device according to the third embodiment.

FIG. 16 is a schematic cross-sectional view of a surrounding area of the display device according to the third embodiment.

FIG. 17 is a schematic plan view of a panel unit in the third embodiment.

FIG. 18A is a schematic cross-sectional view showing a state where droplets are discharged in the manufacturing process of the display device according to the third embodiment.

FIG. 18B is a schematic cross-sectional view showing a state where droplets have adhered.

### DETAILED DESCRIPTION

In general, according to one embodiment, a display device includes a substrate having a display area for displaying an image and a surrounding area around the display area, an organic insulating layer provided in the display area and the surrounding area, a plurality of pixels provided in the display area, the pixels each including a lower electrode, an upper electrode located above the lower electrode, and an organic layer located between the lower electrode and the upper electrode and emitting light based on application of voltage, a first partition provided in the display area and surrounding each of the plurality of pixels, a second partition provided in the surrounding area and connected to the first partition, a third partition provided further outward than the second partition in the surrounding area and spaced apart from the second partition via a slit, and a dam portion provided in the surrounding area and surrounding the organic insulating layer, the second partition, and the third partition. Each of the first partition, the second partition, and the third partition includes a lower portion having conductivity and an upper portion having an end portion protruding relative to a side surface of the lower portion. The third partition is located above the organic insulating layer and is spaced apart from the dam portion.

In general, according to another embodiment, a display device includes a substrate having a display area for displaying an image and a surrounding area around the display area, an organic insulating layer provided in the display area and the surrounding area, a plurality of pixels provided in the display area, the pixels each including a lower electrode, an upper electrode located above the lower electrode, and an organic layer located between the lower electrode and the upper electrode and emitting light based on application of voltage, a first partition provided in the display area and surrounding each of the plurality of pixels, a second partition provided in the surrounding area and connected to the first partition, a third partition provided further outward than the second partition in the surrounding area and spaced apart from the second partition via a slit, and a first resin layer covering the display area and part of the surrounding area. Each of the first partition, the second partition, and the third partition includes a lower portion having conductivity and an upper portion having an end portion protruding relative to a side surface of the lower portion. An end portion of the organic insulating layer is located between an end portion of the substrate and the third partition. The substrate has an outer circumference area located between the end portion of the organic insulating layer and the end portion of the substrate. Further, the first resin layer covers the third partition and does not overlap the outer circumference area.

The configuration of a display device of each embodiment can improve the yield.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the figures, an X-axis, a Y-axis, and a Z-axis orthogonal to each other are described to facilitate understanding as needed. A direction parallel to the X-axis is referred to as an X-direction. A direction parallel to the Y-axis is referred to as a Y-direction. A direction parallel to the Z-axis is referred to as a Z direction. The Z direction is the normal direction of a plane including the X-direction and the Y-direction. When various elements are viewed parallel to the Z direction, the appearance is defined as a plan view.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone, and a wearable terminal.

### First Embodiment

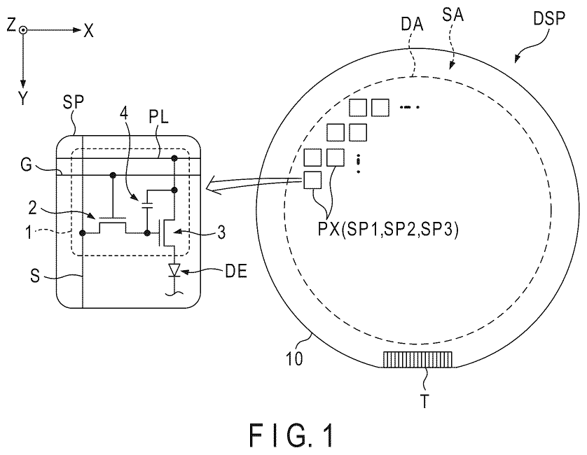

FIG. 1 is a view showing a configuration example of a display device DSP of the first embodiment. The display device DSP comprises an insulating substrate 10. The substrate 10 has a display area DA for displaying an image and a surrounding area SA around the display area DA. The substrate 10 may be glass or a resinous film having flexibility.

In the present embodiment, the substrate 10 and the display area DA have a circular shape in plan view. The shape of each of the substrate 10 and the display area DA in plan view is not limited to a circular shape and may be another shape such as a rectangular shape, a square shape, or an elliptic shape.

The display area DA comprises a plurality of pixels PX arranged in a matrix in the X-direction and the Y-direction. Each pixel PX includes a plurality of subpixels SP that display different colors. The present embodiment assumes a case where each pixel PX includes a blue subpixel SP1, a green subpixel SP2, and a red subpixel SP3. Each pixel PX may include a subpixel SP that exhibits another color such as white in addition to the subpixels SP1, SP2, and SP3 or instead of one of the subpixels SP1, SP2, and SP3.

The display device DSP further comprises a terminal portion T provided in the surrounding area SA. For example, a flexible printed circuit, which applies voltage and signals for driving the display device DSP is connected to the terminal portion T.

The subpixel SP comprises a pixel circuit 1 and a display element DE driven by the pixel circuit 1. The pixel circuit 1 comprises a pixel switch 2, a drive transistor 3, and a capacitor 4. The pixel switch 2 and the drive transistor 3 are, for example, switching elements constituted by thin-film transistors.

The display area DA has a plurality of scanning lines G supplying the pixel circuit 1 of each subpixel SP with scanning signals, a plurality of signal lines S supplying the pixel circuit 1 of each subpixel SP with video signals, and a plurality of power lines PL. In the example of FIG. 1, the scanning lines G and the power lines PL extend in the X-direction, and the signal lines S extend in the Y-direction. However, the configuration is not limited to this example.

The gate electrode of the pixel switch 2 is connected to the scanning line G. One of the source electrode and the drain electrode of the pixel switch 2 is connected to the signal line S. The other is connected to the gate electrode of the drive transistor 3 and the capacitor 4. In the drive transistor 3, one of the source electrode and the drain electrode is connected to the power line PL and the capacitor 4. The other is connected to a display element DE.

The configuration of the pixel circuit 1 is not limited to the illustrated example. For example, the pixel circuit 1 may comprise more thin-film transistors and capacitors.

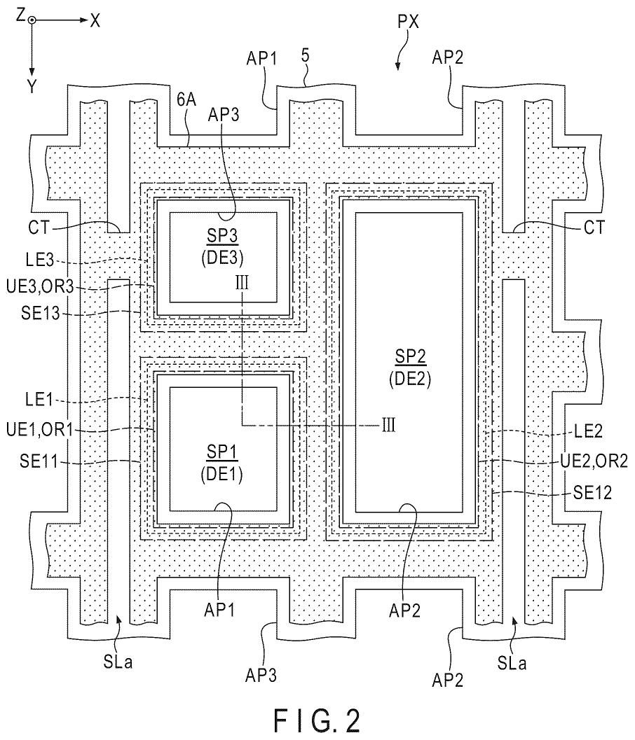

FIG. 2 is a schematic plan view showing an example of the layout of the subpixels SP1, SP2, and SP3 constituting one pixel PX. In the example of FIG. 2, the subpixels SP1 and SP3 are arranged in the Y-direction. Each of the subpixels SP1 and SP3 is adjacent to the subpixel SP2 in the X-direction.

When the subpixels SP1, SP2, and SP3 are arranged in this layout, in the display area DA, a column in which the subpixels SP1 and SP3 are alternately arranged in the Y-direction and a column in which the plurality of subpixels SP2 are repeatedly arranged in the Y-direction are formed. These columns are alternately arranged in the X-direction. The layout of the subpixels SP1, SP2, and SP3 is not limited to the example of FIG. 2.

A rib layer 5 is provided in the display area DA. The rib layer 5 has pixel apertures AP1, AP2, and AP3 in the respective subpixels SP1, SP2, and SP3. In the example of FIG. 2, each of the pixel apertures AP1, AP2, and AP3 has a rectangular shape. The planar size of the pixel aperture AP1 is greater than that of the pixel aperture AP3. The planar size of the pixel aperture AP2 is greater than that of the pixel aperture AP1. The shapes of the pixel aperture AP1, AP2, and AP3 are not limited to this example.

The subpixel SP1 comprises a lower electrode LE1, an upper electrode UE1, and an organic layer OR1, which overlap the pixel aperture AP1. The subpixel SP2 comprises a lower electrode LE2, an upper electrode UE2, and an organic layer OR2, which overlap the pixel aperture AP2. The subpixel SP3 comprises a lower electrode LE3, an upper electrode UE3, and an organic layer OR3, which overlap the pixel aperture AP3.

The lower electrode LE1, the upper electrode UE1, and the organic layer OR1 constitute a display element DE1 of the subpixel SP1. The lower electrode LE2, the upper electrode UE2, and the organic layer OR2 constitute a display element DE2 of the subpixel SP2.

The lower electrode LE3, the upper electrode UE3, and the organic layer OR3 constitute a display element DE3 of the subpixel SP3. Each of the display elements DE1, DE2, and DE3 may further have a cap layer to be described later. The rib layer 5 surrounds each of the display elements DE1, DE2, and DE3.

A conductive partition 6A (the first partition) is provided above the rib layer 5. The partition 6A functions as lines that apply common voltage to the upper electrodes UE1, UE2, and UE3. The partition 6A entirely overlaps the rib layer 5 and has the same planar shape as that of the rib layer 5. The partition 6A surrounds the subpixels SP1, SP2, and SP3.

The partition 6A has a plurality of slits SLa extending in the Y-direction. In the example of FIG. 2, the subpixels SP1, SP2, and SP3 constituting one pixel PX are provided between two slits SLa in the X-direction. Further, the partition 6A has a connection unit CT, which connects portions divided by the slits SLa to one another. The layout of the slits SLa and the connection unit CT is not limited to the example of FIG. 2. For example, slits SLa that are continuous between the both end portions in the Y-direction of the display area DA may be provided.

Sealing layers SE11, SE12, and SE13 (the first sealing layers) are provided in the respective subpixels SP1, SP2, and SP3. The sealing layer SE11 continuously covers the display element DE1 and the partition 6A around the display element DE1. The sealing layer SE12 continuously covers the display element DE2 and the partition 6A around the display element DE2. The sealing layer SE13 continuously covers the display element DE3 and the partition 6A around the display element DE3.

In the example of FIG. 2, the sealing layers SE11, SE12, and SE13 do not overlap the slits SLa. As another example, at least one of the sealing layers SE11, SE12, and SE13 may overlap the slit SLa.

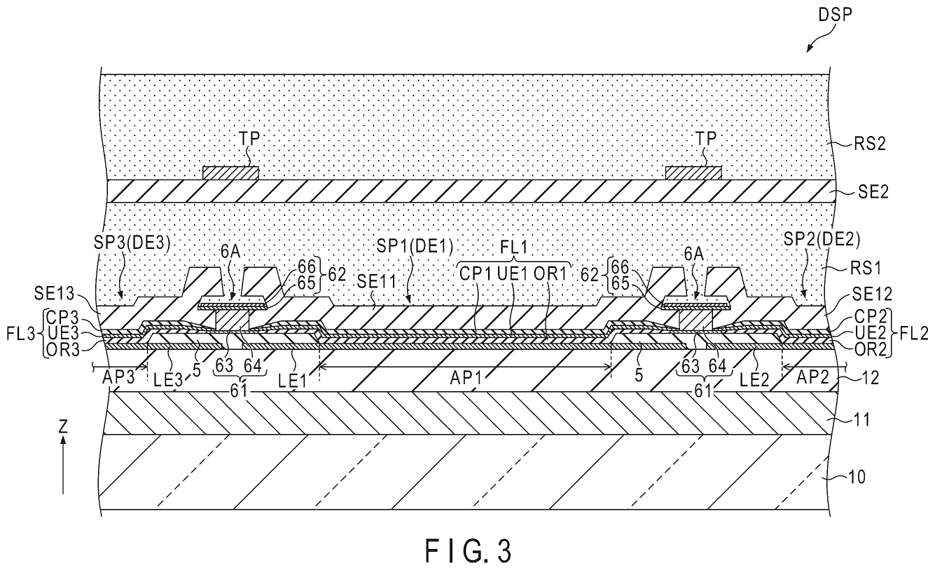

FIG. 3 is a schematic cross-sectional view of the display device DSP along the III-III line of FIG. 2. A circuit layer 11 is provided on the substrate 10 described above. The circuit layer 11 includes various circuits and lines such as the pixel circuit 1, scanning line G, signal line S, and power line PL shown in FIG. 1. The circuit layer 11 is covered with an organic insulating layer 12. The organic insulating layer 12 functions as a planarization film, which planarizes irregularities formed by the circuit layer 11.

The lower electrodes LE1, LE2, and LE3 are provided on the organic insulating layer 12. The rib layer 5 is provided on the organic insulating layer 12 and the lower electrodes LE1, LE2, and LE3. The periphery portions of the lower electrodes LE1, LE2, and LE3 are covered with the rib layer 5. Although not shown in the section of FIG. 3, the lower electrodes LE1, LE2, and LE3 are connected to the respective pixel circuits 1 of the circuit layer 11 through respective contact holes provided in the organic insulating layer 12.

The partition 6A includes a conductive lower portion 61 provided on the rib layer 5 and an upper portion 62 provided on the lower portion 61. The upper portion 62 has a width greater than that of the lower portion 61. That is, the partition 6A has an overhang shape in which the both end portions of the upper portion 62 protrude relative to the side surfaces of the lower portion 61.

In the example of FIG. 3, the lower portion 61 has a bottom layer 63 provided on the rib layer 5, and a stem layer 64 provided on the bottom layer 63. For example, the bottom layer 63 is formed to be thinner than the stem layer 64. In the example of FIG. 3, the both end portions of the bottom layer 63 protrude relative to the side surfaces of the stem layer 64.

In the example of FIG. 3, the upper portion 62 comprises a first top layer 65 and a second top layer 66 provided on the first top layer 65. For example, the width of the second top layer 66 is slightly less than that of the first top layer 65. The configuration is not limited to this example. The first top layer 65 and the second top layer 66 may have the same width.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2, and UE3 contact the lower portions 61 of the partition 6A.

The display element DE1 has a cap layer CP1 covering the upper electrode UE1. The display element DE2 has a cap layer CP2 covering the upper electrode UE2. The display element DE3 has a cap layer CP3 covering the upper electrode UE3. The cap layers CP1, CP2, and CP3 function as optical adjustment layers which improve the extraction efficiency of the light emitted from the organic layers OR1, OR2, and OR3, respectively.

In the following explanation, a multilayer body having the organic layer OR1, the upper electrode UE1, and the cap layer CP1 is called a stacked film FL1. A multilayer body having the organic layer OR2, the upper electrode UE2, and the cap layer CP2 is called a stacked film FL2. A multilayer body having the organic layer OR3, the upper electrode UE3, and the cap layer CP3 is called a stacked film FL3.

Sealing layers SE11, SE12, and SE13 (the first sealing layers) are provided in the respective subpixels SP1, SP2, and SP3. Further, the sealing layer SE11 continuously covers the stacked film FL1 and the partition 6A around the stacked film FL1. Further, the sealing layer SE12 continuously covers the stacked film FL2 and the partition 6A around the stacked film FL2. Further, the sealing layer SE13 continuously covers the stacked film FL3 and the partition 6A around the stacked film FL3.

In the example of FIG. 3, the sealing layer SE11 located on the partition 6A between the subpixels SP1 and SP2 is spaced apart from the sealing layer SE12 located on this partition 6A. The sealing layer SE11 located on the partition 6A between the subpixels SP1 and SP3 is spaced apart from the sealing layer SE13 located on this partition 6A. Two of the sealing layers SE11, SE12, and SE13 may contact each other above the partition 6A.

For example, a gap is formed between each of the sealing layers SE11, SE12, and SE13 and the upper portion 62 of the partition 6A. The stacked films FL1, FL2, and FL3 may be provided in at least part of these gaps.

The sealing layers SE11, SE12, and SE13 are covered with a resin layer RS1 (first resin layer). The resin layer RS1 is covered with a sealing layer SE2 (second sealing layer). The sealing layer SE2 is covered with a resin layer RS2 (second resin layer). The resin layers RS1 and RS2 and the sealing layer SE2 are continuously provided in at least the entire display area DA and partly extend in the surrounding area SA as well.

In the example of FIG. 3, a touch panel electrode TP for detecting touch operations by a user is provided on the sealing layer SE2. For example, the touch panel electrode TP is formed of a metal material and has the same shape as that of the partition 6A in plan view.

A cover member such as a polarizer, a protective film, and a cover glass may be further provided above the resin layer RS2. This cover member may be attached to the resin layer RS2 via, for example, an adhesive layer such as an optical clear adhesive (OCA).

The organic insulating layer 12 is formed of an organic insulating material such as a polyimide. Each of the rib layer 5 and the sealing layers SE11, SE12, SE13, and SE2 is formed of an inorganic insulating material such as a silicon nitride (SiNx), a silicon oxide (Siox), or a silicon oxynitride (SiON). For example, the rib layer 5 is formed of a silicon oxynitride, and each of the sealing layers SE11, SE12, SE13, and SE2 is formed of a silicon nitride. Each of the resin layers RS1 and RS2 is formed of, for example, a resinous material (organic insulating material) such as an epoxy resin or an acrylic resin.

Each of the lower electrodes LE1, LE2, and LE3 has a reflective layer formed of, for example, silver, and a pair of conductive oxide layers covering the upper and lower surfaces of the reflective layer. Each of the conductive oxide layers can be formed of, for example, a transparent conductive oxide such as an indium tin oxide (ITO), an indium zinc oxide (IZO), and an indium gallium zinc oxide (IGZO).

The upper electrodes UE1, UE2, and UE3 are formed of, for example, a metal material such as an alloy of magnesium and silver (MgAg). For example, the lower electrodes LE1, LE2, and LE3 correspond to anodes, and the upper electrodes UE1, UE2, and UE3 correspond to cathodes.

Each of the organic layers OR1, OR2, and OR3 is composed of a plurality of thin films including a light emitting layer. As an example, the organic layers OR1, OR2, and OR3 have a structure in which a hole-injection layer, a hole-transport layer, an electron blocking layer, a light emitting layer, a hole blocking layer, an electron-transport layer, and an electron-injection layer are stacked in this order in the Z direction. The organic layers OR1, OR2, and, OR3 each may have other structures such as a tandem structure including a plurality of light emitting layers.

Each of the cap layers CP1, CP2, and CP3 has, for example, a multilayer structure in which a plurality of transparent layers are stacked. These transparent layers could have a layer formed of an inorganic material and a layer formed of an organic material. These transparent layers have refractive indices different from one another. For example, the refractive indices of these transparent layers are different from the refractive indices of the upper electrodes UE1, UE2, and UE3 and the refractive indices of the sealing layers SE11, SE12, and SE13. At least one of the cap layers CP1, CP2, and CP3 may be omitted.

Each of the bottom layer 63 and stem layer 64 of the partition 6A is formed of a metal material. For the metal material of the bottom layer 63, for example, molybdenum, titanium, a titanium nitride (TiN), a molybdenum-tungsten alloy (MoW), or a molybdenum-niobium alloy (MoNb) can be used. For the metal material of the stem layer 64, for example, aluminum, an aluminum-neodymium alloy (AlNd), an aluminum-yttrium alloy (AlY), or an aluminum-silicon alloy (AlSi) can be used. The stem layer 64 may be composed of an insulating material.

The first top layer 65 of the partition 6A is formed of, for example, a metal material. The second top layer 66 of the partition 6A is formed of, for example, a conductive oxide. For the metal material forming the first top layer 65, for example, titanium, a titanium nitride, molybdenum, tungsten, a molybdenum-tungsten alloy, or a molybdenum-niobium alloy can be used. For the conductive oxide forming the second top layer 66, for example, ITO or IZO can be used. The upper portion 62 may have three or more layers or may consist of a single layer. The upper portion 62 may further have a layer formed of an insulating material.

Common voltage is applied to the partition 6A. This common voltage is applied to each of the upper electrodes UE1, UE2, and UE3 that contact the lower portions 61. The lower electrodes LE1, LE2, and LE3 are supplied with pixel voltages according to the video signals of the signal lines S through the respective pixel circuits 1 provided in the subpixels SP1, SP2, and SP3.

The organic layers OR1, OR2, and OR3 emit light in response to the application of a voltage. Specifically, when a potential difference is formed between the lower electrode LE1 and the upper electrode UE1, the light emitting layer of the organic layer OR1 emits light in a blue wavelength range. When a potential difference is formed between the lower electrode LE2 and the upper electrode UE2, the light emitting layer of the organic layer OR2 emits light in a green wavelength range. When a potential difference is formed between the lower electrode LE3 and the upper electrode UE3, the light emitting layer of the organic layer OR3 emits light in a red wavelength range.

As another example, the light emitting layers of the organic layers OR1, OR2, and OR3 may emit light of the same color (for example, white). In this case, the display device DSP may comprise a color filter that converts light emitted from the light emitting layers into light of the colors corresponding to those of the subpixels SP1, SP2, and SP3. In addition, the display device DSP may comprise a layer including quantum dots that are excited by the light emitted from the light emitting layers to generate the light of the colors corresponding to those of the subpixels SP1, SP2, and SP3.

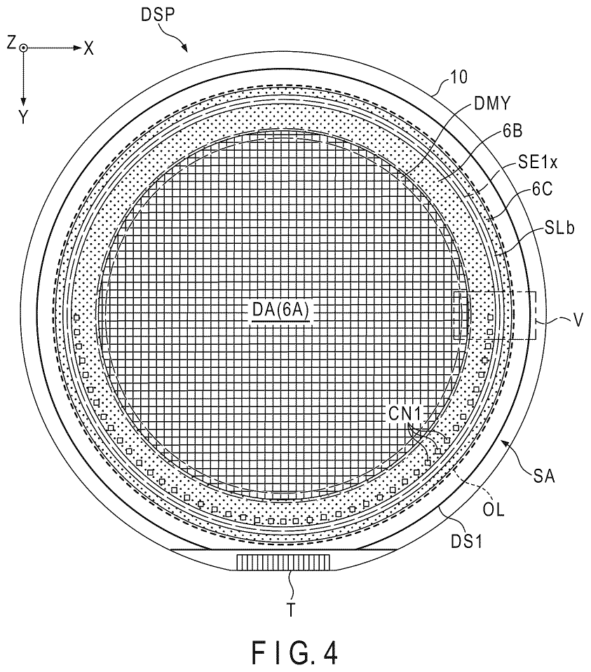

FIG. 4 is a schematic plan view of the display device DSP. In the example of this figure, a dummy pixel area DMY, a partition 6B (the second partition), a partition 6C (the third partition), a sealing layer SE1x (the first sealing layer), and a dam structure DS1 are provided in the surrounding area SA. For example, each of the dummy pixel area DMY, the partition 6B, the partition 6C, the sealing layer SE1x, and the dam structure DS1 has a circular shape concentric with the display area DA.

The dummy pixel area DMY surrounds the display area DA. The partition 6B is located on the outside of the dummy pixel area DMY (a side farther from the display area DA). The partition 6C is located on the outside of the partition 6B. In the example of FIG. 4, the partitions 6B and 6C surround the display area DA. The partitions 6B and 6C are spaced apart from each other via a slit SLb having a ring shape. The slit SLb surrounds the display area DA, the dummy pixel area DMY, and the partition 6B.

The sealing layer SElx overlaps the partition 6B but does not overlap the partition 6C. In the example of FIG. 4, the sealing layer SE1x surrounds the display area DA.

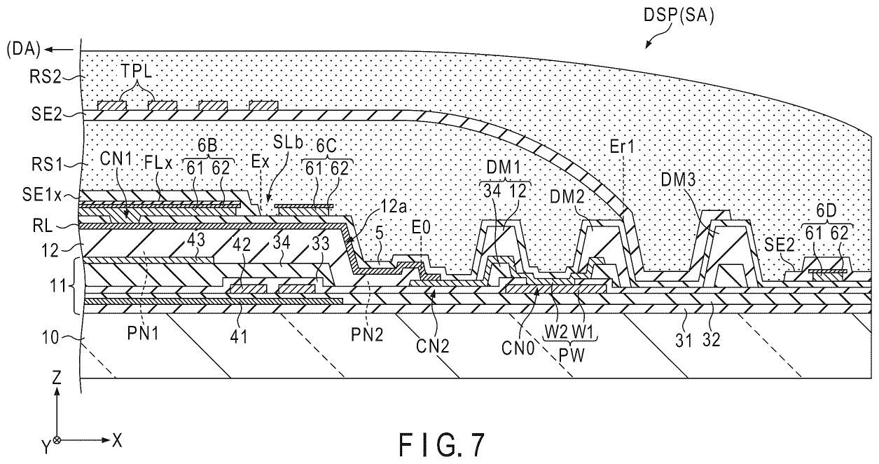

The partition 6B is connected to the relay layer RL and the power supply line PW that are provided on the lower layer via a plurality of contact portions CN1 (refer to FIG. 7). The power supply line PW is connected to the terminal portion T and supplies the partition 6B with common voltage. The partition 6A provided in the display area DA is connected to the partition 6B. That is, common voltage of the power supply line PW is supplied to the partition 6A via the partition 6B and then supplied to the upper electrodes UE1, UE2, and UE3, which contact the partition 6A.

In the example of FIG. 4, the plurality of contact portions CN1 are arcuately provided in the terminal portion T side. Each of the contact portions CN1 is provided between the slit SLb and the display area DA and overlaps the partition 6B.

The dam structure DS1 is located on the outside of the partition 6C and surrounds the display area DA, the dummy pixel area DMY, the partition 6B, the partition 6C, and the sealing layer SE1x. The terminal portion T is located on the outside of the dam structure DS1.

The resin layer RS1 shown in FIG. 3 is formed by the ink-jet method. This process is to be described later in detail. FIG. 4 shows an outer edge OL of the area toward which droplets are discharged at the time of forming the resin layer RS1 by broken lines. The outer edge OL is located between the partition 6B and the dam structure DS1.

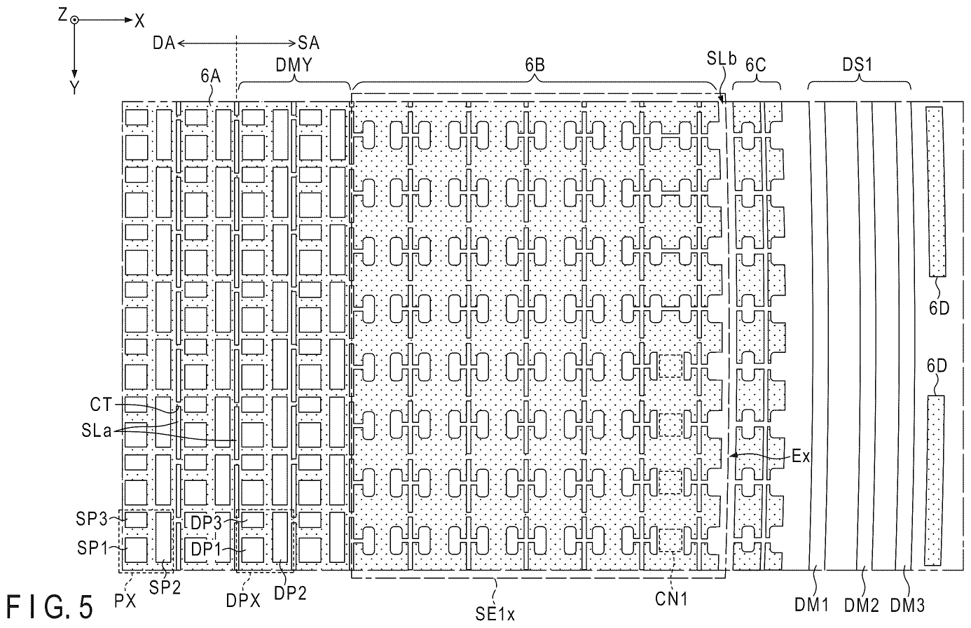

FIG. 5 is a schematic plan view in which the area surrounded by the frame V of FIG. 4 is enlarged. A plurality of dummy pixels DPX are provided in the dummy pixel area DMY. For example, each dummy pixel DPX includes dummy subpixels DP1, DP2, and DP3. Each of the dummy subpixels DP1, DP2, and DP3 has the configuration similar to that of the respective subpixels SP1, SP2, and SP3 shown in FIG. 2.

That is, the dummy subpixel DP1 comprises the lower electrode LE1, the organic layer OR1, the upper electrode UE1, and the sealing layer SE11. The dummy subpixel DP2 comprises the lower electrode LE2, the organic layer OR2, the upper electrode UE2, and the sealing layer SE12. The dummy subpixel DP3 comprises the lower electrode LE3, the organic layer OR3, the upper electrode UE3, and the sealing layer SE13.

However, the dummy subpixels DP1, DP2, and DP3 are configured not to emit light. This configuration may be realized by, for example, disconnecting part of the pixel circuit 1 in each of the dummy subpixels DP1, DP2, and DP3. The pixel apertures AP1, AP2, and AP3 may be omitted in the dummy subpixels DP1, DP2, and DP3, respectively. Thus, the rib layer 5 is interposed between the organic layers OR1, OR2, and OR3 and the lower electrodes LE1, LE2, and LE3. Thus, a voltage for making the organic layers OR1, OR2, and OR3 to emit light is not supplied to these organic layers OR.

Part of the partition 6A is located in the dummy pixel area DMY and surrounds each of the plurality of dummy pixels DPX. More specifically, the partition 6A surrounds each of the dummy subpixels DP1, DP2, and DP3. The shapes and layout of the apertures of the partition 6A in each of the dummy subpixels DP1, DP2, and DP3 are the same as those of the apertures of the partition 6A in the respective subpixels SP1, SP2, and SP3. The slits SLa and the connection unit CT shown in FIG. 2 are provided in the dummy pixel area DMY as well.

The dam structure DS1 comprises a dam portion DM1 surrounding the partition 6C, a dam portion DM2 surrounding the dam portion DM1, and a dam portion DM3 surrounding the dam portion DM2. The partition 6C is spaced apart from the dam portion DM1. The number of the dam portions that the dam structure DS1 comprises is not limited to three. For example, each of the dam portions DM1, DM2, and DM3 has a circular shape surrounding the display area DA.

In the example of FIG. 5, a plurality of partitions 6D are provided in the outside of the dam portion DM3. These partitions 6D are provided along the dam portion DM3 and are spaced apart from one another.

The sealing layer SE1x entirely overlaps the partition 6B. An end portion Ex of the sealing layer SE1x is located in the slit SLb. The sealing layer SE1x is formed of the same inorganic insulating material as those of the sealing layers SE11, SE12, and SE13.

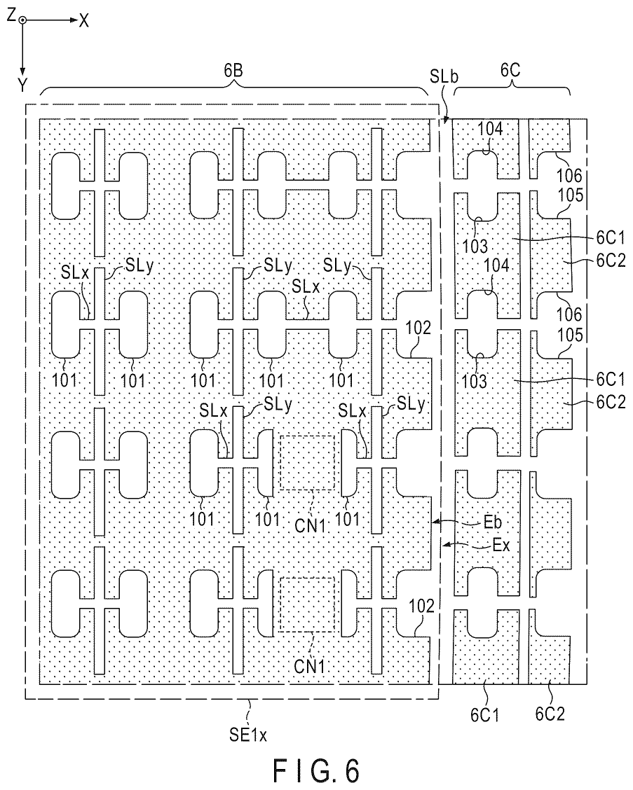

FIG. 6 is a schematic plan view in which part of FIG. 5 is further enlarged. The partition 6B has a plurality of apertures 101. For example, the aperture 101 has a shape elongated in the Y-direction. The shape of the aperture 101 is not limited to this example.

The partition 6B further includes a slit SLx extending in the X-direction and a slit SLy extending in the Y-direction. The slit SLx connects two or more apertures 101 that are adjacent to each other in the X-direction. The slit SLy intersects the slit SLx.

In the example of FIG. 6, the partition 6B further has a recess portion 102 concaved relative to an end portion Eb of the partition 6B. The recess portion 102 is connected to the aperture 101 adjacent thereto in the X-direction by the slit SLx.

The contact portion CN1 entirely overlaps the partition 6B. As shown in FIG. 6, the width in the X-direction of the aperture 101 may be reduced in the vicinity of the contact portion CN1. This configuration can ensure space for installing the contact portions CN1.

The partition 6C comprises a plurality of partitions 6C1 provided along the slit SLb and a plurality of partitions 6C2 located on the outside of the partitions 6C1. Each of the plurality of partitions 6C1 and each of the plurality of partitions 6C2 are spaced apart from each other.

The partition 6C1 has recess portions 103 and 104. The partition 6C2 has recess portions 105 and 106. The recess portions 103 and 104 of adjacent partitions 6C1 form the same shape as the aperture 101. The recess portions 105 and 106 of adjacent partitions 6C2 form the same shape as the recess portion 102. FIG. 7 is a schematic cross-sectional view of the surrounding area SA of the display device DSP. This figure omits the illustration of the aperture 101 and the slits SLx and SLy of the partition 6B. Further, the partition 6C is not divided into the partitions 6C1 and 6C2. Instead, the partition 6C is integrally shown.

The partitions 6B, 6C, and 6D have the same structure as that of the partition 6A. That is, the partitions 6B, 6C, and 6D have the lower portion 61 and the upper portion 62. The lower portion 61 has the bottom layer 63 and the stem layer 64. The upper portion 62 has the first top layer 65 and the second top layer 66. At the end portion of each of the partitions 6B, 6C, and 6D, the upper portion 62 protrudes relative to the side surfaces of the lower portion 61.

The circuit layer 11 shown in FIG. 3 has inorganic insulating layers 31, 32, and 33 formed of an inorganic insulating material, an organic insulating layer 34 formed of an organic insulating material, and metal layers 41, 42, and 43. The inorganic insulating layer 31 covers the upper surface of the substrate 10. The metal layer 41 is provided on the inorganic insulating layer 31. The inorganic insulating layer 32 covers the metal layer 41. The metal layer 42 is provided on the inorganic insulating layer 32. The inorganic insulating layer 33 covers the metal layer 42. The organic insulating layer 34 covers the inorganic insulating layer 33. The metal layer 43 is provided on the organic insulating layer 34 and is covered with the organic insulating layer 12.

The each of the dam portions DM1, DM2, and DM3 protrudes toward the upper side of the substrate 10. In the example of FIG. 7, the dam portion DM1 consists of the organic insulating layers 12 and 34. Similarly, the dam portions DM2 and DM3 consist of the organic insulating layers 12 and 34. In other words, in the present embodiment, the dam portions DM1, DM2, and DM3 are formed of the same materials as the organic insulating layers 12 and 34 in the same layers as the organic insulating layers 12 and 34.

The power line PW to which common voltage is applied is provided below the dam portions DM1 and DM2. The power line PW has a first line W1 formed of the metal layer 42 and a second line W2 formed of the metal layer 43.

In the example of FIG. 7, the first line W1 and the second line W2 contact each other in a contact portion CN0 located between the dam portions DM1 and DM2. Part of the second line W2 is located between the organic insulating layers 12 and 34 in each of the dam portions DM1 and DM2.

In the surrounding area SA, the conductive relay layer RL, which connects the partition 6B and the power supply line PW to each other, and the rib layer 5 are provided. For example, the relay layer RL is formed of the same material and process as those of the lower electrodes LE1, LE2, and LE3 described above.

The relay layer RL is located on the display area DA side (the left side in the figure) relative to the dam portion DM1 and covers the organic insulating layer 12. The rib layer 5 continuously covers the relay layer RL and the dam portions DM1, DM2, and DM3.

The partitions 6B, 6C, and 6D are provided on the rib layer 5. The partition 6B contacts the relay layer RL in the contact portion CN1 shown also in FIG. 4 to FIG. 6. More specifically, the rib layer 5 is open in the contact portions CN1. The lower portion 61 of the partition 6B (specifically, the bottom layer 63) contacts the relay layer RL through this opening. The contact portion CN1 is provided above the organic insulating layer 12.

The relay layer RL contacts the second line W2 of the power supply line PW in a contact portion CN2. The contact portion CN2 is located between the end portion E0 of the organic insulating layer 12 and the dam portion DM1 in plan view.

A stacked film FLx is provided on the partition 6B. The partition 6B and the stacked film FLx are covered with the sealing layer SElx. The stacked film FLx is formed by the same process and material as those of any of the stacked films FL1, FL2, and FL3 shown in FIG. 3. The sealing layer SE1x is formed by the same process and material as those of any of the sealing layers SE11, SE12, and SE13 shown in FIG. 3. The present embodiment assumes cases where the stacked film FLx and the sealing layer SE1x are respectively formed as the same process and material as those of the stacked film FL3 and the sealing layer SE13, respectively. That is, the stacked film FLx has the upper electrode UE3, the organic layer OR3, and the cap layer CP3.

The partition 6C are not covered with the stacked film FLx and the sealing layer SE1x. As shown also in FIG. 5 and FIG. 6, the end portion Ex of the sealing layer SE1x is located in the slit SLb between the partitions 6B and 6C.

The resin layer RS1, the sealing layer SE2, and the resin layer RS2 shown in FIG. 3 are provided above the sealing layer SE1x. Further, a touch panel line TPL connected to the touch panel electrode TP shown in FIG. 3 is provided on the sealing layer SE2. For example, the touch panel line TPL is formed of the same material as the touch panel electrode TP.

The resin layer RS1 covers the sealing layer SE1x and the rib layer 5. Further, the resin layer RS1 directly covers the partition 6C. In the manufacturing of the display device DSP, the dam portions DM1, DM2, and DM3 function to dam up the resin layer RS1 that is uncured. In the example of FIG. 7, the end portion Er1 of the resin layer RS1 is located above the dam portion DM2. That is, the resin layer RS1 partly covers the dam portions DM1 and DM2. The position of the end portion Er1 is not limited to this example.

The sealing layer SE2 covers the end portion Er1 of the resin layer RS1. The sealing layer SE2 contacts the rib layer 5 in an area located further outward than the end portion Er1 (the right side in the figure). The sealing layer SE2 covers the partition 6D. In the example of FIG. 7, the sealing layer SE2 is removed in the vicinity of the dam portion DM3. The resin layer RS1 is surrounded by the sealing layer SElx, the rib layer 5, and the sealing layer SE2. This configuration prevents the moisture intrusion into the resin layer RS1.

As shown in FIG. 7, the organic insulating layer 12 may have a first portion PN1 and a second portion PN2 thinner than the first portion PN1. The second portion PN2 is formed in the periphery of the first portion PN1. That is, the second portion PN2 covers the first portion PN1 in plan view. Each of the partition 6B, the partition 6C, the stacked film FLx, and the sealing layer SE1x is located above the first portion PN1.

In the example of FIG. 7, the organic insulating layer 34 is provided below the first portion PN1 but not provided below the second portion PN2. A step portion 12a is formed in the organic insulating layer 12 in the vicinity of the end portion of the organic insulating layer 34. For example, of the organic insulating layer 12, the portion that is closer to the dam portion DM1 relative to the step portion 12a corresponds to the second portion PN2.

The relay layer RL covers the first portion PN1, the second portion PN2, and the step portion 12a. If the organic insulating layer 12 does not have the second portion PN2, the step portion 12a becomes steeper. If the relay layer RL is formed to cover this steep step portion 12a, the relay layer RL may be deformed. To the contrary, providing the second portion PN2 can decrease the influence of the step portion 12a, and thus the relay layer RL can be sufficiently formed.

The sectional structure shown in FIG. 7 can be applied to any position of the surrounding area SA except the vicinity of the terminal portion T. The configuration of the surrounding area SA is not necessarily limited to that shown in FIG. 7. For example, the organic insulating layer 12 may not have the second portion PN2. The shape of the structure for connecting the partition 6B and the power supply line PW together can be changed according to the position of the power supply line PW, the layer configuration of the circuit layer 11, and the like.

The following describes an example of the manufacturing method of the display device DSP. In the manufacturing of the display device DSP, a large mother substrate is fabricated, the mother substrate comprising a plurality of areas (panel units) each including a unit corresponding to the display device DSP.

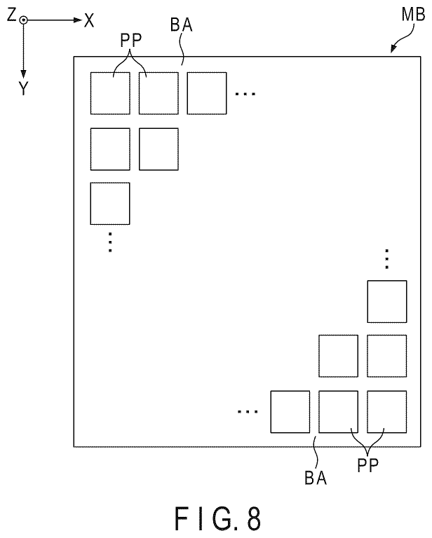

FIG. 8 is a schematic plan view of a mother substrate MB (a mother substrate for a display device) according to the present embodiment. For example, the mother substrate MB has a rectangular shape as shown in the figure. However, the mother substrate MB may have another shape such as a circular shape.

The mother substrate MB comprises a plurality of panel units PP provided in a matrix and a margin area BA around these panel units PP. In the example of FIG. 8, the panel units PP are arranged in the X-direction and the Y-direction via the margin area BA. The layout of the panel units PP in the mother substrate MB is not limited to this example. As another example, some of the panel units PP may be arranged without interposing the margin area BA therebetween.

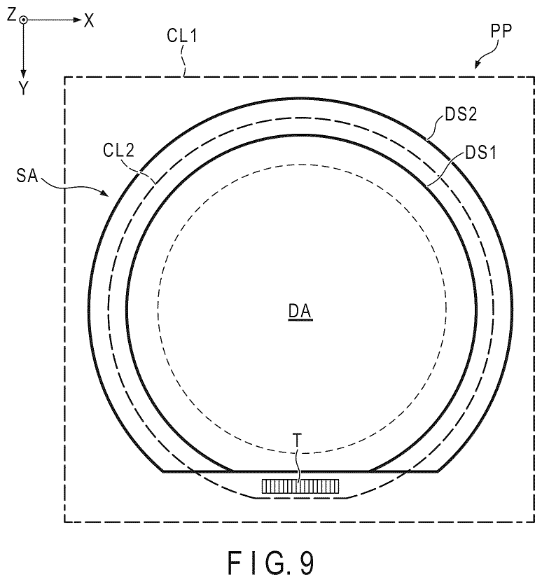

FIG. 9 is a schematic plan view of the panel unit PP. The outer shape of the panel unit PP corresponds to a cut line CL1 for cutting out each panel unit PP from the mother substrate MB.

Each panel unit PP has the display area DA and the surrounding area SA. The surrounding area SA in the panel unit PP corresponds to the area between the display area DA and the cut line CL1.

The surrounding area SA further has a cut line CL2, which is the outer shape of the substrate 10 of the display device DSP. In the manufacturing of the display device DSP, the panel unit PP is cut out from the mother substrate MB along the cut line CL1. Further, the display device DSP is cut out from the panel unit PP along the cut line CL2.

In addition to the dam structure DS1, the panel unit PP comprises a dam structure DS2. The dam structure DS2 functions to dam up the resin layer RS2 that is uncured. For example, the dam structure DS2 has a plurality of dam portions formed of the organic insulating layers 12 and 34 in the same manner as the dam portions DM1, DM2, and DM3.

The dam structure DS1 is located between the cut line CL2 and the display area DA and surrounds the display area DA. The dam structure DS2 is located between the cut lines CL1 and CL2 and surrounds the cut line CL2. In the example of FIG. 9, the dam structures DS1 and DS2 merge in the vicinity of the terminal portion T. This merged portion passes between the terminal portion T and the display area DA.

The most part of the cut line CL2 is located between the dam structures DS1 and DS2. In the example of FIG. 9, the cut line CL2 is located on the outside of the dam structures DS1 and DS2 in the vicinity of the terminal portion T. That is, the cut line CL2 traverses the dam structure DS2 in the vicinity of the terminal portion T.

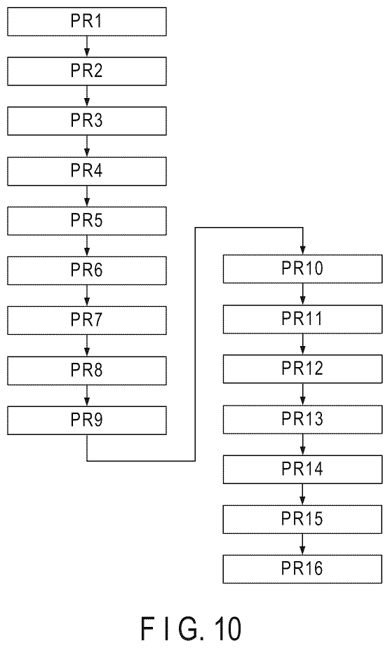

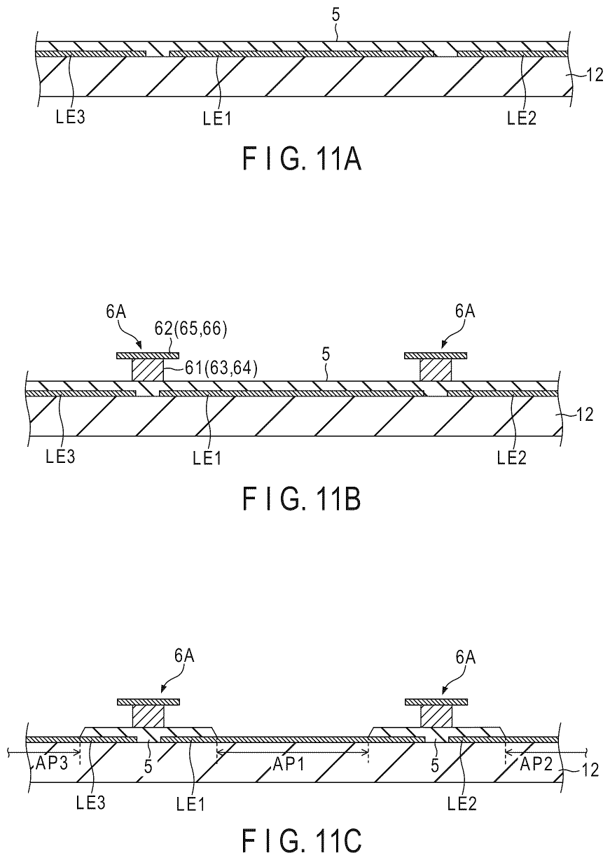

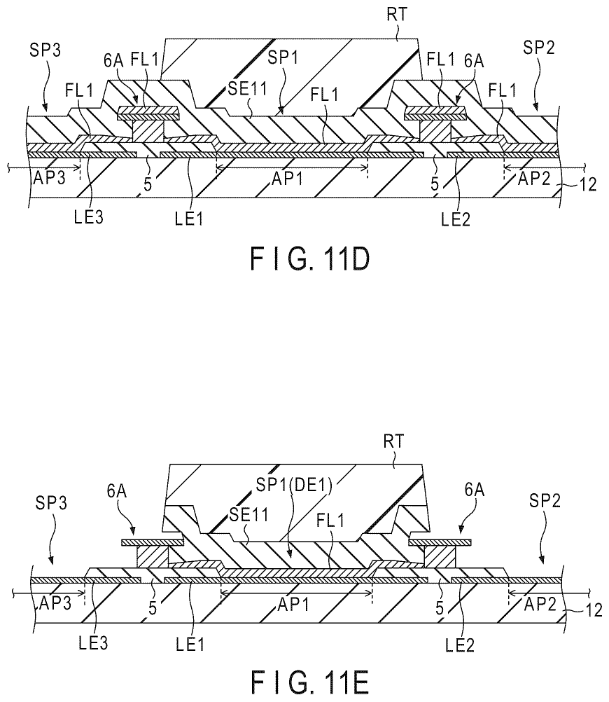

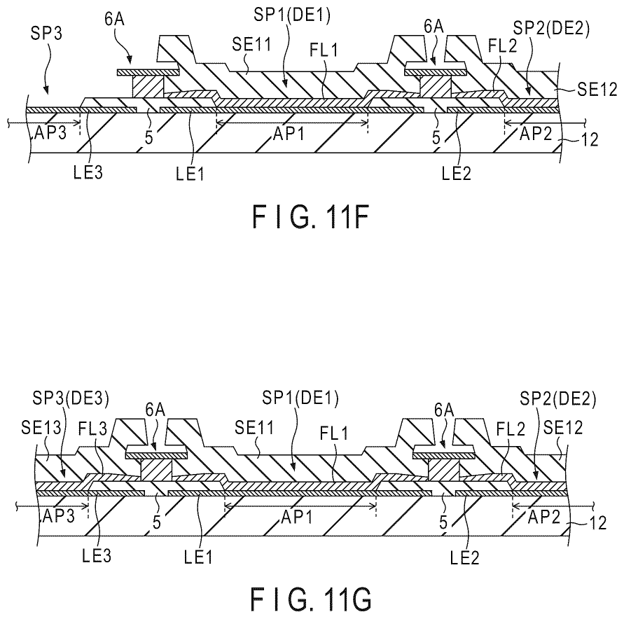

FIG. 10 is a flowchart showing an example of the manufacturing method of the display device DSP. FIG. 11A to FIG. 11G are schematic cross-sectional views showing the manufacturing process of the display device DSP. FIG. 11A to FIG. 11G mainly focus on the display area DA and omit the elements below the organic insulating layer 12.

In the formation of the panel units PP, first, the circuit layer 11 including the inorganic insulating layers 31, 32, and 33, the organic insulating layer 34, the metal layers 41, 42, and 43, and the like are formed on the substrate 10 of the mother substrate MB (process PR1 in FIG. 10). Further, the organic insulating layer 12 covering the circuit layer 11 is formed (process PR2 in FIG. 10). At this time, the dam structures DS1 and DS2 are formed as well.

After the process PR2, as shown in FIG. 11A, the lower electrodes LE1, LE2, and LE3 are formed on the organic insulating layer 12 (process PR3 in FIG. 10). Further, as shown in FIG. 11A, the rib layer 5 covering the lower electrodes LE1, LE2, and LE3 is formed in the entire mother substrate MB (process PR4 in FIG. 10). At this time, the pixel apertures AP1, AP2, and AP3 are not provided in the rib layer 5. The rib layer 5 may be formed by chemical vapor deposition (CVD).

After the formation of the rib layer 5, the partition 6A is formed on the rib layer 5, as shown in FIG. 11B (process PR5 in FIG. 10). The partitions 6B, 6C, and 6D of the surrounding area SA are formed together with the partition 6A.

Next, as shown in FIG. 11C, the pixel apertures AP1, AP2, and AP3 are formed in the rib layer 5 (process PR6 in FIG. 10). The pixel apertures AP1, AP2, and AP3 may be formed prior to the formation of the partitions 6A, 6B, 6C, and 6D.

After the process PR6, a process for forming the display element DE1 is performed (process PR7 in FIG. 10). In the formation of the display element DE1, the stacked film FL1 and the sealing layer SE11 are formed first as shown in FIG. 11D. As shown in FIG. 3, the stacked film FL1 has the organic layer OR1 contacting the lower electrode LE1 through the pixel aperture AP1, the upper electrode UE1 covering the organic layer OR1, and the cap layer CP1 covering the upper electrode UE1. For example, the organic layer OR1, the upper electrode UE1, and the cap layer CP1 may be formed by vapor deposition. For example, the sealing layer SE11 may be formed by CVD.

The stacked film FL1 and the sealing layer SE11 are formed in the entire mother substrate MB including the surrounding area SA and the margin area BA as well as the display area DA of each panel unit PP. The stacked film FL1 is divided by the partitions 6A, 6B, 6C, and 6D having overhang shapes. The sealing layer SE11 continuously covers the portions into which the stacked film FL1 is divided, and the partitions 6A, 6B, 6C, and 6D.

Subsequently, the stacked film FL1 and the sealing layer SE11 are patterned. In this patterning, as shown in FIG. 11D, a resist RT is provided on the sealing layer SE11. The resist RT covers the subpixel SP1 and part of the partition 6A around the subpixel SP1.

Subsequently, an etching process using the resist RT as a mask is performed. By this process, of the stacked film FL1 and the sealing layer SE11, the portions that are exposed from the resist RT are removed, as shown in FIG. 11E. In other words, of the stacked film FL1 and the sealing layer SE11, the portions that overlap the lower electrode LE1 remain, and the other portions are removed. This process forms the display element DE1 in the subpixel SP1. For example, this etching process removes the stacked film FL1 and the sealing layer SE11 in the surrounding area SA and the margin area BA. This etching process may include wet etching and dry etching performed in order for the sealing layer SE11, the cap layer CP1, the upper electrode UE1, and the organic layer OR1. After these etching processes, the resist RT is removed (stripped).

After the process PR7, a process for forming the display element DE2 is performed (process PR8 in FIG. 10). The display element DE2 can be formed by the same procedure as that of the display element DE1. That is, in the formation of the display element DE2, the stacked film FL2 and the sealing layer SE12 are formed in the entire mother substrate MB. The stacked film FL2 includes the organic layer OR2 contacting the lower electrode LE2 through the pixel aperture AP2, the upper electrode UE2 covering the organic layer OR2, and the cap layer CP2 covering the upper electrode UE2, as shown in FIG. 3.

The organic layer OR2, the upper electrode UE2, and the cap layer CP2 may be formed by, for example, vapor deposition. The sealing layer SE12 may be formed by, for example, CVD. Patterning these stacked film FL2 and sealing layer SE12 forms the display element DE2 in the subpixel SP2, as shown in FIG. 11F. For example, the etching in this patterning removes the stacked film FL2 and the sealing layer SE12 in the surrounding area SA and the margin area BA.

After the process PR8, a process for forming the display element DE3 is performed (process PR9 in FIG. 10). The display element DE3 can be formed by the same procedures as those of the display elements DE1 and DE2. Specifically, when the display element DE3 is formed, the stacked film FL3 and the sealing layer SE13 are formed in the entire mother substrate MB. The stacked film FL3 includes, the organic layer OR3 contacting the lower electrode LE3 through the pixel aperture AP3, the upper electrode UE3 covering the organic layer OR3, and the cap layer CP3 covering the upper electrode UE3, as shown in FIG. 3.

The organic layer OR3, the upper electrode UE3, and the cap layer CP3 may be formed by, for example, vapor deposition. The sealing layer SE13 may be formed by, for example, CVD. Patterning these stacked film FL3 and sealing layer SE13 forms the display element DE3 in the subpixel SP3, as shown in FIG. 11G.

For example, the etching in this patterning removes the stacked film FL3 and the sealing layer SE13 in the most of the surrounding area SA and margin area BA. Of the stacked film FL3 and the sealing layer SE13, the portion that covers the partition 6B remains. In this manner, the remaining portion corresponds to the stacked film FLx and the sealing layer SE1x.

Here, the above description assumes that the display elements DE1, DE2, and DE3 are formed in this order. However, the display elements DE1, DE2, and DE3 may be formed in another order.

After the process PR9, the resin layer RS1 is formed (process PR10 in FIG. 10). The resin layer RS1 may be formed inside the dam structure DS1 by, for example, the ink-jet method. After the process PR10, the sealing layer SE2 is formed by, for example, CVD (process PR11 in FIG. 10).

After the process PR11, etching for removing the rib layer 5 and the sealing layer SE2 that cover the terminal portion T is performed (process PR12 in FIG. 10). The etching is, for example, dry etching.

After the process PR12, the touch panel electrode TP and the touch panel line TPL are formed on the sealing layer SE2 (process PR13 in FIG. 10). Further, the resin layer RS2 is formed (process PR14 in FIG. 10). The resin layer RS2 may be formed inside the dam structure DS2 by, for example, the ink-jet method. The dam structure DS2 functions to dam up the resin layer RS2 that is uncured.

After the process PR14, the mother substrate MB is cut along the cut line CL1 (process PR15 in FIG. 10). Further, the panel unit PP is cut along the cut line CL2 (process PR16 in FIG. 10). This completes the display device DSP. For example, laser cutting with infrared irradiation along the cut lines CL1 and CL2 may be adopted for cutting in the processes PR15 and PR16. The cutting in the processes PR15 and PR16 may be performed by other methods such as scribe cutting.

The embodiment described above can improve the yield of the display device DSP. The stacked films FL1, FL2, and FL3 formed by vapor deposition may have poor adherence to the base. Thus, the stacked films FL1, FL2, and FL3 and the sealing layers SE11, SE12, and SE13 covering these stacked films may be stripped from the base in the manufacturing of the display device DSP.

This stripping tends to occur in cases where the stacked films FL1, FL2, and FL3 are continuously formed in a wide range. In the display area DA, the stacked films FL1, FL2, and FL3 are divided into pieces by the partition 6A. Thus, the stripping is suppressed.

In the present embodiment, the partition 6B having the plurality of apertures 101 (refer to FIG. 6) and the partition 6C divided into the partitions 6C1 and 6C2 are provided in the surrounding area SA. This configuration divides the stacked films FL1, FL2, and FL3 into pieces and suppresses the stripping in the surrounding area SA as well.

Further, the configuration of the display device DSP according to the present embodiment can achieve, for example, effects described below.

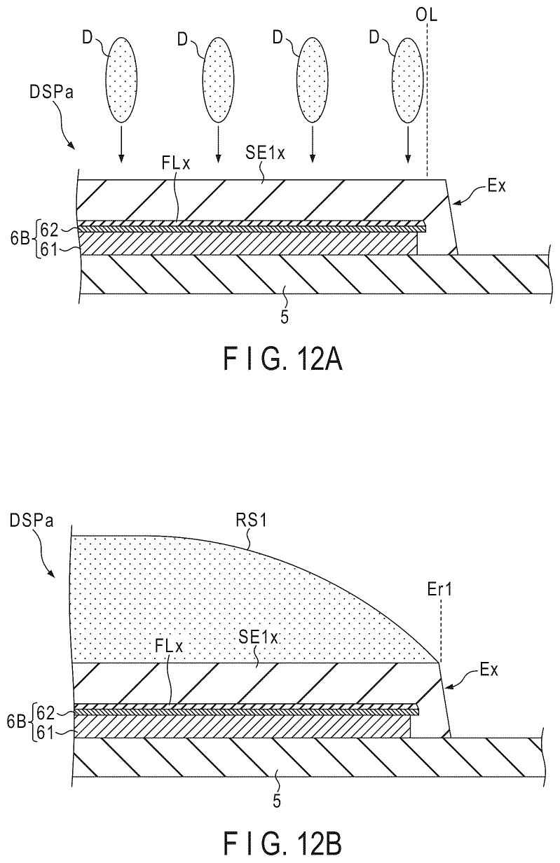

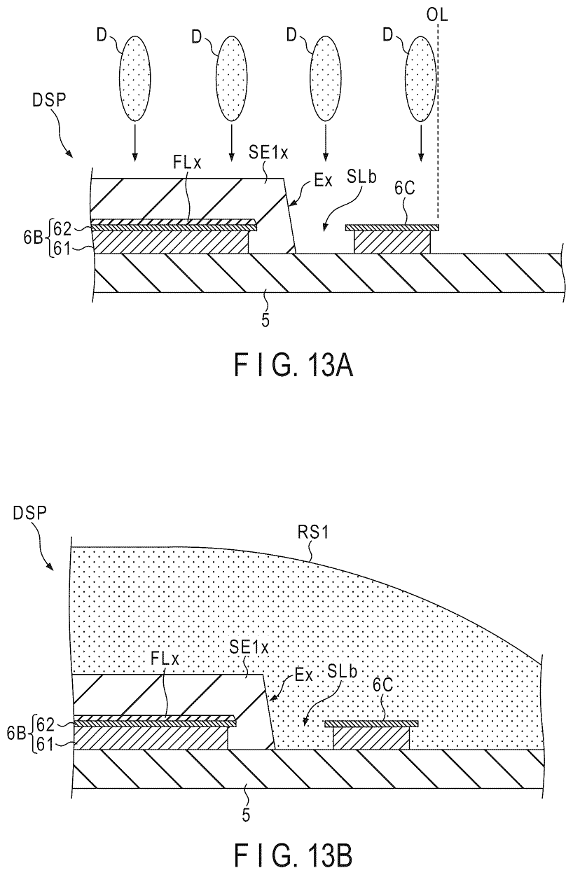

FIG. 12A and FIG. 12B are schematic cross-sectional views of a display device DSPa according to a comparative example. FIG. 13A and FIG. 13B are schematic cross-sectional views of the display device DSP of the present embodiment. These figures focus on the vicinity of the end portion Ex of the sealing layer SE1x.

FIG. 12A and FIG. 13A show the state where droplets D are discharged toward the mother substrate MB when the resin layer RS1 is formed by the ink-jet method in the above process PR10. FIG. 12B and FIG. 13B show the state after the droplets D have adhered.

In the comparative example of FIG. 12A, the partition 6C is not provided. Further, the outer edge OL of the area toward which the droplets D are discharged is located at the position overlapping the sealing layer SE1x. That is, the droplets D do not adhere to the portion positioned further outward than the end portion Ex (right side in the figure) of the sealing layer SE1x.

The droplets D adhering to the sealing layer SE1x in the comparative example spread and form the resin layer RS1, for example, as shown in FIG. 12B. At this time, the spreading of the resin layer RS1 may be inhibited by the surface tension in the vicinity of the end portion Ex. Thus, unlike the one shown in FIG. 7, the end portion Er1 of the resin layer RS1 may fail to reach the dam portions DM1 and DM2.

When formed in the manner shown in FIG. 12B, the sealing layer SE2 covers the steep step formed by the end portions Ex and Er1. In this case, cracks or gaps may be formed in the sealing layer SE2 formed of an inorganic insulating material, forming a path of moisture intrusion.

To address this, the outer edge OL of the area toward which droplets D are discharged may be located further outward than the end portion Ex. However, in view of the formation accuracy of the resin layer RS1, a certain distance has to be provided between each of the dam portions DM1, DM2, and DM3 and the outer edge OL. Thus, in some cases, it is difficult to shift the outer edge OL outward.

As an alternative measure, the end portion Ex may be shifted to the display area DA side (left side in the figure). However, this requires shifting the end portion of the partition 6B together with the sealing layer SE1x. Any area in which the stacked film FLx is exposed from the sealing layer SE1x may allow moisture to infiltrate the display area DA through the stacked film FLx. Thus, to completely seal the stacked film FLx on the partition 6B, the end portion of the partition 6B must also be shifted to the display area DA side such that the sealing layer SElx is formed further outward than the end portion of the partition 6B. However, this configuration may form a wide area between the partition 6B and the dam portion DM1, and the stripping may occur in this area.

On the other hand, in the configuration of the present embodiment shown in FIG. 13A, the partition 6C is provided on the outside of the partition 6B. In this configuration, the partition 6C can suppress the above stripping even in the area between the partition 6B and the dam portion DM1. Thus, the partition 6B can be shifted to the display area DA side, compared to the configuration of FIG. 12A. In association with this, the end portion Ex of the sealing layer SElx can also be shifted to the display area DA side, compared to the configuration of FIG. 12A. For example, the end portion Ex can be located in the slit SLb.

For example, when the outer edge OL is located at the same position in the comparative example and in the present embodiment, the droplets D can adhere to the area further outward than the end portion Ex, as shown in FIG. 13A. In this case, the droplets D spreading on the end portion Ex and the droplets D spreading in the area further outward than the end portion Ex merge. Thus, the resin layer RS1 that sufficiently covers the end portion Ex can be formed. Thus, the above steep step in the comparative example is not formed. As a result, cracks and the like in the sealing layer SE2 are suppressed. Thus, the display device DSP with excellent moisture resistance can be achieved.

Furthermore, as explained with reference to FIG. 4 to FIG. 6, when the end portion Ex of the sealing layer SElx is provided in the slit SLb around the entire circumference, moisture infiltration through the stacked film FLx can be sufficiently suppressed. Even if the partitions 6B and 6C are completely divided by the slit SLb, the contact portion CN1 is located at the position overlapping the partition 6B. Thus, the supply of common voltage to the display area DA through the partition 6B is not inhibited.

Furthermore, unlike the comparative example shown in FIG. 12B, the present embodiment has no steep steps. Thus, defects in the application of liquid resins such as various resists, which are applied after the formation of the resin layer RS1, are suppressed. Such liquid resins include, for example, a resist for processing the rib layer 5 and the sealing layer SE2 in the process PR12, and a resist for processing the touch panel electrode TP and the touch panel line TPL in the process PR13.

The display device DSP may include a plurality of color filters corresponding to the colors of the subpixels SP1, SP2, and SP3, and a black matrix located at the boundaries of the subpixels SP1, SP2, and SP3. For example, these color filters and black matrix may be provided above the sealing layer SE2. Reduction in the step caused by the end portions Er1 and Ex can suppress defects in the application of the resins that are materials forming the color filters and black matrix.

### Second Embodiment

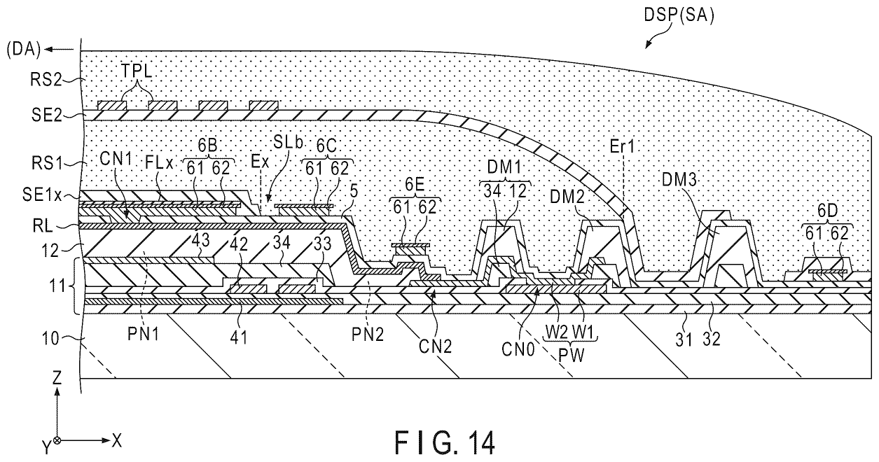

FIG. 14 is a schematic cross-sectional view of a surrounding area SA of a display area DA according to the second embodiment. The configuration shown in this figure differs from the configuration shown in FIG. 7 in that a partition 6E (the fourth partition) is further provided between the partition 6C and the dam portion DM1. For example, the partition 6E is provided above the second portion PN2 of the organic insulating layer 12.

In the same manner as the partitions 6B, 6C, and 6D, the partition 6E has the lower portion 61 and the upper portion 62. The lower portion 61 of the partition 6E has a bottom layer 63 and a stem layer 64. The upper portion 62 of the partition 6E has a first top layer 65 and a second top layer 66.

In this configuration, the partition 6E can suppress the stripping of the stacked films FL1, FL2, and FL3 and the sealing layers SE11, SE12, and SE13 in the manufacturing of the display device DSP even in the area between the partition 6C and the dam portion DM1. This further improves the yield of the display device DSP.

In addition to the example shown in FIG. 14, partitions may be provided between the dam portions DM1 and DM2, or between dam portions DM2 and DM3. Further, the partitions may also be provided to overlap the dam portions DM1, DM2, and DM3.

### Third Embodiment

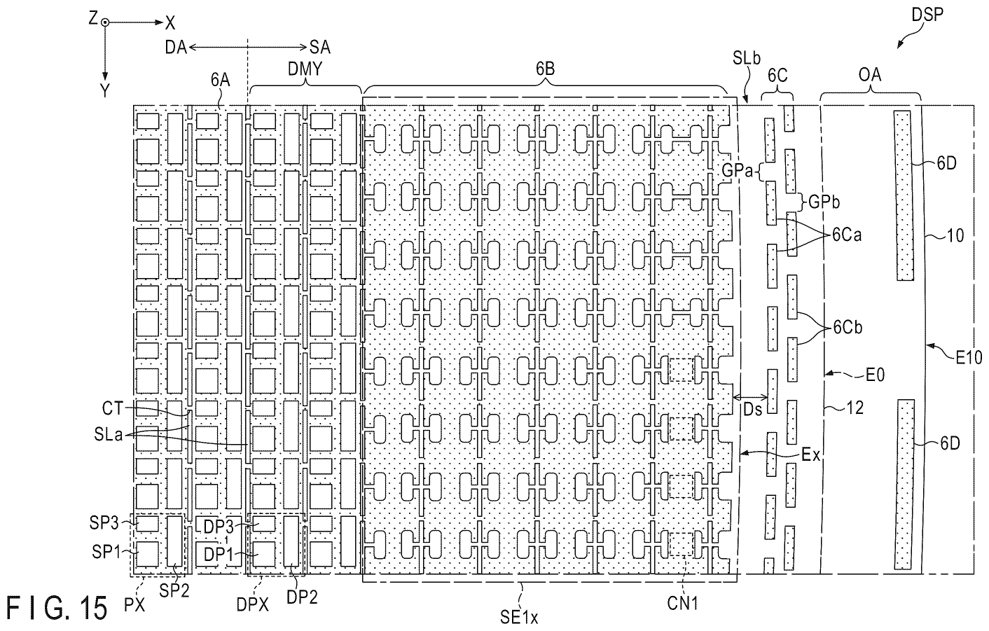

FIG. 15 is a schematic plan view showing the configuration of a display device DSP according to the third embodiment. This plan view shows the configuration of the vicinity of an end portion E10 of a substrate 10.

In this embodiment, the dam structure DS1 (dam portions DM1, DM2, and DM3) is not provided in the surrounding area SA. This can reduce the width of the surrounding area SA compared to the first embodiment (refer to FIG. 4).

An end portion E0 of an organic insulating layer 12 is closer to a display area DA side than the end portion E10 of the substrate 10 is. Thus, the substrate 10 has an outer circumference area OA in which the organic insulating layer 12 is not provided. The outer circumference area OA is located between the end portions E0 and E10.

In the same manner as the first embodiment, the partition 6A (the first partition) is provided in the display area DA, and the partition 6B (the second partition), the partition 6C (the third partition), and the partition 6D are provided in the surrounding area SA. The planar shapes of the partitions 6A, 6B, and 6D are identical to those shown in FIG. 5 and FIG. 6.

The end portion E0 of the organic insulating layer 12 is located between the end portion E10 of the substrate 10 and the partition 6C. That is, the partitions 6B and 6C overlap the organic insulating layer 12. On the other hand, the partition 6D is located in the outer circumference area OA but does not overlap the organic insulating layer 12.

The partition 6C is spaced apart from the partition 6B via a slit SLb. In the example of FIG. 15, the partition 6C includes a plurality of partitions 6Ca and a plurality of partitions 6Cb. For example, the partitions 6Ca and 6Cb have a rectangular shape or an arcuate shape that are elongated along the end portion Ex of a sealing layer SE1x.

The plurality of partitions 6Ca are located between the end portion Ex of the sealing layer SE1x and the end portion E0 of the organic insulating layer 12 and are arranged along the end portions Ex and E0 with a constant interval between each other. The plurality of partitions 6Cb are located between the column of the partitions 6Ca and the end portion E0, and are arranged at a constant interval from each other in the same manner as the partitions 6Ca. In terms of suppressing the stripping of the stacked films FL1, FL2, and FL3 and the sealing layers SE11, SE12, and SE13 in the manufacturing of the display device DSP, a distance Ds between the partition 6B and the partition 6Ca is preferably less than 80 μm.

In the example of FIG. 15, a gap GPa between adjacent partitions 6Ca and a gap GPb between adjacent partitions 6Cb are misaligned in the arrangement direction of the partitions 6Ca and 6Cb (in the direction along the end portions Ex and E0). The gaps GPa and GPb do not necessarily have to be misaligned in the entire surrounding area SA; they may be aligned in at least part of the surrounding area SA.

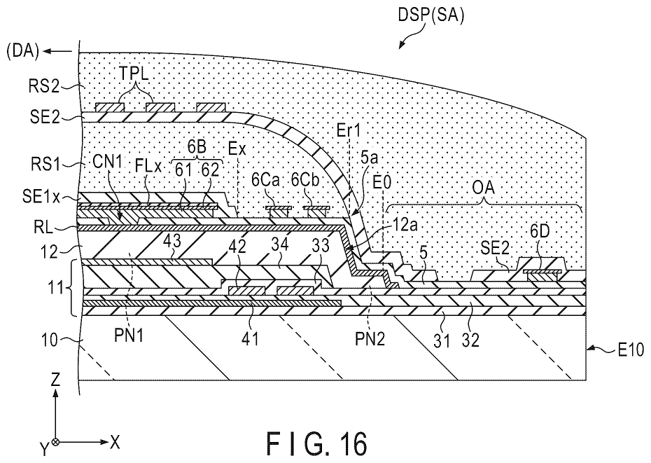

FIG. 16 is a schematic cross-sectional view of the surrounding area SA of the display device DSP according to the third embodiment. In the same manner as the example shown in FIG. 7, the organic insulating layer 12 has the first portion PN1 and the second portion PN2 thinner than the first portion PN1. The organic insulating layer 12 may not have the second portion PN2.

For example, neither the organic insulating layer 12 nor an organic insulating layer 34 is provided in the surrounding area OA. However, the organic insulating layer 34 may be provided in at least part of the outer circumference area OA.

In the present embodiment, an end portion Er1 of the resin layer RS1 is located above the organic insulating layer 12. More specifically, in the example of FIG. 16, the end portion Er1 is located near a corner portion 5a of the rib layer 5 formed by the step portion 12a. That is, the resin layer RS1 does not overlap the outer circumference area OA.

Each of the partitions 6Ca and 6Cb has the lower portion 61 and the upper portion 62 in the same manner as the partition 6B. As described above, the partitions 6Ca and 6Cb are located between the end portion Ex of the sealing layer SE1x and the end portion E0 of the organic insulating layer 12. That is, the partitions 6Ca and 6Cb are not covered with the sealing layer SElx. The partitions 6Ca and 6Cb are located on the rib layer 5 and are covered with the resin layer RS1.

In the same manner as the first embodiment, the resin layer RS1 is covered with the sealing layer SE2. The sealing layer SE2 contacts the rib layer 5 in the outer circumference area OA. In the example of FIG. 16, the sealing layer SE2 is divided in the outer circumference area OA.

The configurations shown in FIG. 15 and FIG. 16 can be applied to any position in the surrounding area SA except for the vicinity of the terminal portion T. The configuration of the surrounding area SA is not necessarily limited to those shown in these figures. For example, in the same manner as the partition 6E in the second embodiment shown in FIG. 14, a partition may be provided above the upper portion of the second portion PN2 or between the end portion E0 and the partition 6D.

The following describes an example of the manufacturing method of the display device DSP according to the present embodiment. The display device DSP according to the present embodiment can be manufactured in the same processes as those in the first embodiment described with reference to FIG. 10 and FIG. 11A to FIG. 11G. That is, in the manufacturing of the display device DSP, a large mother substrate is manufactured, which includes a plurality of panel units PP each including a unit corresponding to the display device DSP. Then, the display device DSP is cut out from this mother substrate.

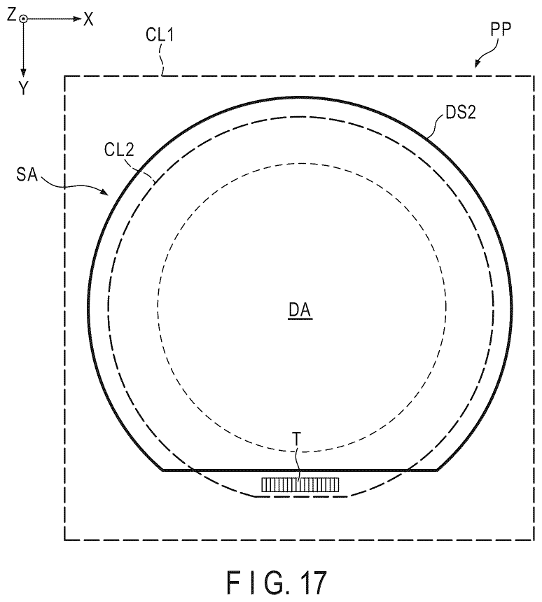

FIG. 17 is a schematic plan view of the panel unit PP according to the present embodiment. In the same manner as the example of FIG. 9, the panel unit PP has the display area DA, the surrounding area SA, the cut line CL2, and the dam structure DS2. However, in the present embodiment, the panel unit PP does not comprise the dam structure DS1.

In this manner, the present embodiment does not comprise the dam structure DS1. Thus, the spreading pattern of the droplets D at the time of forming the resin layer RS1 by the inkjet method in the present embodiment differs from that shown in FIG. 13A and FIG. 13B. The following describes this point.

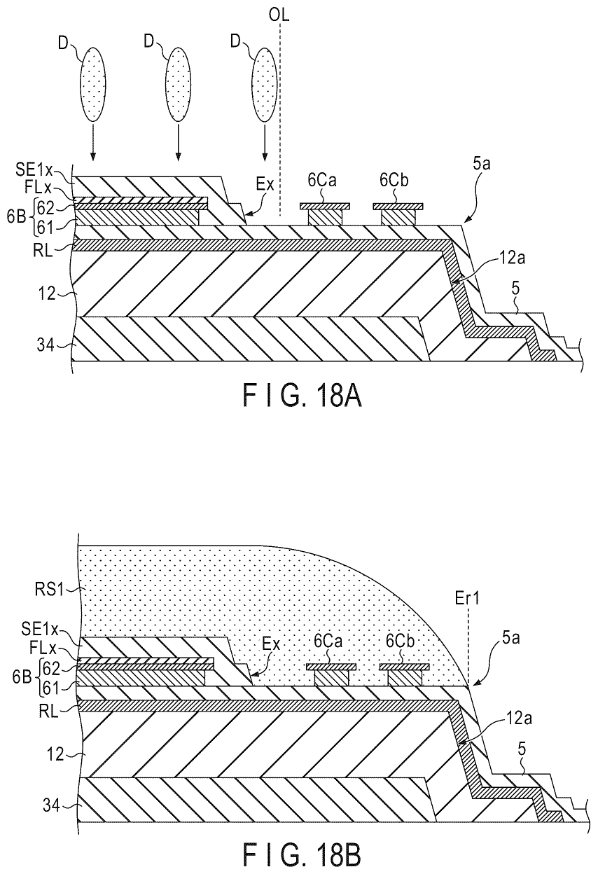

FIG. 18A is a schematic cross-sectional view showing a state where the droplets D are discharged in the manufacturing of the display device DSP according to the present embodiment. FIG. 18B is a schematic cross-sectional view showing a state where the droplets D have adhered.

In the present embodiment, the outer edge OL of the area toward which the droplets D are discharged is located between the end portion Ex of the sealing layer SE1x and the corner portion 5a of the rib layer 5. More specifically, in the example of FIG. 18A, the outer edge OL is located between the end portion Ex and the partition 6Ca. The position of the outer edge OL is not limited to this example, and may overlap the partitions 6Ca and 6Cb or the area between them.

The droplets D adhered to the sealing layer SE1x spread as shown in FIG. 18B. At this time, the partitions 6Ca and 6cb prevent the droplets D from spreading. Furthermore, in the vicinity of the corner portion 5a, the surface tension acts on the droplets D that have spread beyond the partitions 6Ca and 6Cb. Thus, the spread of the droplets D stops in the vicinity of the corner portion 5a, and the resin layer RS1 whose end portion Er1 is located in the vicinity of the corner portion 5a is formed.

The configuration shown in FIG. 15 in which the gap GPa between adjacent partitions 6Ca and the gap GPb between adjacent partitions 6Cb are misaligned can suitably suppress the spreading of droplets D. In contrast, a configuration in which the gaps GPa and GPa overlap cannot sufficiently suppress the spreading of the droplets D at that overlapping portion. Thus, the droplets D may spread beyond the corner portion 5a. In contrast, the configuration in which the gaps GPa and GPa are misaligned suppresses the spread of the droplets D by at least one of the partitions 6Ca and 6Cb.

Further, in cases where the partitions 6Ca and 6Cb are linear without the gaps GPa and Gb, the spread of the droplets D may be excessively suppressed. This may result in areas where the resin layer RS1 fails to be formed up to the corner portion 5a. In contrast, providing the gaps GPa and GPb at each position allows the droplets D to pass through appropriately and can form the resin layer RS1 up to the corner portion 5a.

Furthermore, when the partition 6C is required to suppress the spreading of the droplets D further, an additional partition may be provided between the partition 6Cb and the corner portion 5a. Further, when the function of the partition 6C that suppresses the spreading of the droplets D needs to be weaken, one of the partitions 6Ca and 6Cb may be omitted.

In each of the above embodiments, the term “partition” includes various overhanging structures. Even if the overhanging structure has a shape different from the partition disclosed in each embodiment, the portion protruding laterally corresponds to the “upper portion” and the portion recessed below of the portion corresponds to the “lower portion”.

All of the display devices that can be implemented by a person of ordinary skill in the art through arbitrary design changes to the display device disclosed as each embodiment described above come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or by adding or omitting a step or changing the condition of a step, all of the modifications fall within the scope of the present invention as long as they are in keeping with the spirit of the invention.

Further, other effects which may be obtained from the above embodiments and are self-explanatory from the descriptions of the specification or can be arbitrarily conceived by a person of ordinary skill in the art are considered as the effects of the present invention as a matter of course.

What is claimed is:

1. A display device, comprising:
a substrate having a display area for displaying an image and a surrounding area around the display area;
an organic insulating layer provided in the display area and the surrounding area;
a plurality of pixels provided in the display area, the pixels each including a lower electrode, an upper electrode located above the lower electrode, and an organic layer located between the lower electrode and the upper electrode and emitting light based on application of voltage;
a first partition provided in the display area and surrounding each of the plurality of pixels;
a second partition provided in the surrounding area and connected to the first partition;
a third partition provided further outward than the second partition in the surrounding area and spaced apart from the second partition via a slit; and
a dam portion provided in the surrounding area and surrounding the organic insulating layer, the second partition, and the third partition, wherein
each of the first partition, the second partition, and the third partition includes a lower portion having conductivity and an upper portion having an end portion protruding relative to a side surface of the lower portion, and
the third partition is located above the organic insulating layer and is spaced apart from the dam portion.

2. The display device of claim 1, wherein
the second partition, the dam portion, and the third partition surround the display area.

3. The display device of claim 1, further comprising:
a first sealing layer formed of an inorganic insulating material and covering a stacked film including the organic layer and the upper electrode, wherein
the first sealing layer covers the second partition and does not cover the third partition.

4. The display device of claim 3, wherein
an end portion of the first sealing layer is located in the slit.

5. The display device of claim 4, wherein
the slit surrounds the display area.

6. The display device of claim 3, further comprising:
a first resin layer covering the display area and part of the surrounding area, wherein
the first resin layer covers at least part of the dam portion.

7. The display device of claim 6, wherein
the first resin layer directly covers the third partition.

8. The display device of claim 6, further comprising:
a second sealing layer formed of an inorganic insulating material and covering the first resin layer.

9. The display device of claim 1, wherein
the organic insulating layer has a first portion and a second portion formed in periphery of the first portion and thinner than the first portion.

10. The display device of claim 9, wherein
the second partition and the third partition are provided above the first portion.

11. The display device of claim 9, further comprising:
a fourth partition provided above the second portion.

12. The display device of claim 1, further comprising:
a power supply line provided in the surrounding area; and
a relay layer having conductivity, provided in the surrounding area, and connecting the second partition and the power supply line.

13. The display device of claim 12, wherein
the second partition contacts the relay layer in a first contact portion provided above the organic insulating layer.

14. The display device of claim 13, wherein
the relay layer contacts the power supply line in a second contact portion located between an end portion of the organic insulating layer and the dam portion in plan view.

15. The display device of claim 13, wherein
the first contact portion is located between the slit and the display area in plan view.

16. The display device of claim 1, wherein
the second partition has a plurality of apertures.

17. The display device of claim 16, wherein
the second partition further has a slit connected to at least one of the plurality of apertures.

18. A display device, comprising:
a substrate having a display area for displaying an image and a surrounding area around the display area;
an organic insulating layer provided in the display area and the surrounding area;
a plurality of pixels provided in the display area, the pixels each including a lower electrode, an upper electrode located above the lower electrode, and an organic layer located between the lower electrode and the upper electrode and emitting light based on application of voltage;
a first partition provided in the display area and surrounding each of the plurality of pixels;
a second partition provided in the surrounding area and connected to the first partition;
a third partition provided further outward than the second partition in the surrounding area and spaced apart from the second partition via a slit; and
a first resin layer covering the display area and a part of the surrounding area, wherein
each of the first partition, the second partition, and the third partition includes a lower portion having conductivity and an upper portion having an end portion protruding relative to a side surface of the lower portion,
an end portion of the organic insulating layer is located between an end portion of the substrate and the third partition,
the substrate has an outer circumference area located between the end portion of the organic insulating layer and the end portion of the substrate, and
the first resin layer covers the third partition and does not overlap the outer circumference area.

19. The display device of claim 18, further comprising:
a first sealing layer formed of an inorganic insulating material and covering a stacked film including the organic layer and the upper electrode, wherein
the first sealing layer is located below the first resin layer, covers the second partition, but does not cover the third partition.

20. The display device of claim 18, further comprising:
a rib layer formed of an inorganic insulating material and located below the second partition and the third partition; and
a second sealing layer formed of an inorganic insulating material and covering the first resin layer, wherein
the rib layer and the second sealing layer contact in the outer circumference area.
